(19) United States
(12) Patent Application Publication
(10) Pub. No.: US 2020/0152557 A1
(43) Pub. Date: May 14, 2020

(54) PACKAGE STRUCTURE AND PACKAGING PROCESS

(71) Applicant: Delta Electronics Int'l (Singapore) Pte Ltd, Singapore (SG)

(72) Inventor: Beng Beng Lim, Singapore (SG)

(21) Appl. No.: 16/513,480

(22) Filed: Jul. 16, 2019

(30) Foreign Application Priority Data
Nov. 9, 2018 (SG) 10201809987Y

(51) Int. Cl. H01L 23/495; H01L 23/00; H05K 1/02; H01L 23/367; H01L 23/522; H01L 23/498

(52) U.S. Cl. CPC H01L 23/49568; H01L 24/09; H05K 1/0209; H01L 2224/02372; H01L 23/5226; H01L 23/49861; H01L 23/367

(57) ABSTRACT

A package structure includes a carrier, at least one electronic component, a first insulation layer, a heat spreading layer, a second insulation layer, plural re-distribution blocks, a passivation layer, and a heat dissipation device. The electronic component is disposed in a recess of the carrier and has plural conducting terminals. The first insulation layer is formed on a second surface of the carrier. The heat spreading layer is formed on the first insulation layer. The second insulation layer is formed on a first surface of the carrier. The re-distribution blocks are formed on the second insulation layer. Each re-distribution block includes at least one conductive via disposed in the second insulation layer and in contact with corresponding one of the conductive terminals. The passivation layer is formed on the re-distribution blocks and covers portions of the re-distribution blocks. The heat dissipation device is disposed on the heat spreading layer.

### FIELD OF THE INVENTION

The present invention relates to a package structure and a packaging process, and more particularly to a package structure capable of enhancing the heat dissipating efficiency and achieving compact purposes. The present invention also relates to a packaging process for the above-mentioned package structure.

### BACKGROUND OF THE INVENTION

Recently, the general trends in designing electronic devices are toward small size, light weightiness and easy portability. Moreover, with increasing development of electronic industries, the internal circuitries of the electronic devices are gradually modularized. In other words, plural electronic components are integrated into a single circuit module. For example, a power module is one of the widely-used circuit modules. An example of the power module includes a DC-to-DC converter, a DC-to-AC converter, an AC-to-DC converter, or the like. After the electronic components (e.g. chips, capacitors, resistors, inductors, transformers, diodes and transistors) are integrated as a power module, the power module may be installed on a motherboard or a system circuit board.

Conventionally, the electrical connection inside the power module is made by wire bonding. Since it is necessary to retain a wire bonding area on the substrate, the space utilization of the substrate is limited and the thickness of the power module fails to be reduced. Under this circumstance, it is difficult to increase the power density and achieve compact purpose.

Recently, an embedded approach, which is without any bonding wire, is employed in the packaging process for the power module to further reduce the package foot-print and enhance the performance at the same time. However, when the electronic component embedded within an insulation layer of the embedded package structure generates a great amount of heat during working, the heat may only be dissipated away in a single direction so that the heat dissipating efficiency of the conventional package structure isn't satisfied. Furthermore, the conventional package structure is not only complex but also high packaging process cost.

Therefore, there is a need of providing an improved package structure and packaging process in order to eliminate the above drawbacks.

### SUMMARY OF THE INVENTION

An object of an embodiment of the present invention provides a package structure, in which one or more electronic components are disposed in at least one recess of a thick lead frame and a multiple sides cooling mechanism is employed to dissipate the heat to the surroundings. Consequently, the overall thickness of the package structure is reduced, and the heat dissipating efficiency is enhanced.

An object of other embodiment of the present invention provides a package structure, in which at least one electronic component and at least one passive component are separately and horizontally disposed in a lead frame, covered by insulation layers and electrically connected via a plurality of re-distribution blocks, and wire bonding might be omitted. Consequently, the overall thickness of the package structure is reduced, and the high power density and compact purpose are achieved.

An object of a further embodiment of the present invention provides a packaging process for a slim and easily fabricated package structure. The packaging process is simplified and cost-efficient.

In accordance with an aspect of an embodiment of the present invention, a package structure is provided. The package structure includes a carrier, at least one electronic component, a first insulation layer, a heat spreading layer, a second insulation layer, a plurality of re-distribution blocks, a passivation layer and a heat dissipation device. The carrier has a first surface, a second surface and at least one recess, wherein the first surface is opposite to the second surface, and the at least one recess is concavely formed on the first surface of the carrier. The at least one electronic component is disposed in the at least one recess, wherein each of the at least one electronic component has a first surface, a second surface and a plurality of conducting terminals, the first surface is opposite to the second surface, the plurality of conducting terminals are formed on the first surface of the electronic component, and the first surface of the electronic component is coplanar with the first surface of the carrier. The first insulation layer is formed on the second surface of the carrier. The heat spreading layer is formed on the first insulation layer. The second insulation layer is formed on the first surface of the carrier and covers the at least one electronic component disposed in the at least one recess. A plurality of re-distribution blocks are formed on the second insulation layer and separated with each other, wherein each of the plurality of re-distribution blocks includes at least one conductive via disposed in the second insulation layer and in contact with corresponding one of the plurality of conductive terminals. The passivation layer is formed on the plurality of the re-distribution blocks and covering portions of the plurality of the re-distribution blocks. The heat dissipation device is disposed on the heat spreading layer.

In accordance with another aspect of an embodiment of the present invention, a packaging process is provided. The packaging process includes the following steps. Firstly, a semi-package structure is provided. The semi-package structure includes a carrier, at least one electronic component, a first insulation layer, a heat spreading layer and a second insulation layer. The carrier has a first surface, a second surface and at least one recess, and the at least one recess is concavely formed on the first surface of the carrier. The at least one electronic component is disposed in the at least one recess, each of the at least one electronic component has a first surface, a second surface and a plurality of conducting terminals, the plurality of conducting terminals are formed on the first surface of the electronic component, and the first surface of the electronic component is coplanar with the first surface of the carrier. The first insulation layer is formed on the second surface of the carrier, the heat spreading layer is formed on the first insulation layer, and the second insulation layer is formed on the first surface of the carrier and covers the at least one electronic component. Then, portion of the second insulation layer is removed to form a plurality of via holes corresponding in position with the plurality of conductive terminals of the electronic component. Thereafter, a plurality of re-distribution blocks are formed on the second insulation layer, wherein the plurality of re-distribution blocks are separated with each other, and each of the plurality of the re-distribution blocks includes at least one conductive via disposed in corresponding one of the plurality of via holes of the second insulation layer and in contact with corresponding one of the plurality of conductive terminals. Then, a passivation layer is formed on the plurality of re-distribution blocks and covers portions of the plurality of re-distribution blocks. Finally, a heat dissipation device is disposed on the heat spreading layer.

The above contents of the embodiments of the present invention will become more readily apparent to those ordinarily skilled in the art after reviewing the following detailed description and accompanying drawings, in which:

### BRIEF DESCRIPTION OF THE DRAWINGS

FIG. 1A is a schematic cross-sectional view illustrating a package structure according to a first embodiment of the present invention;

FIG. 1B is a schematic cross-sectional view illustrating the package structure according to a second embodiment of the present invention;

FIG. 2A is a schematic cross-sectional view illustrating the package structure according to a third embodiment of the present invention;

FIG. 2B is a schematic cross-sectional view illustrating the package structure according to a fourth embodiment of the present invention;

FIG. 3A is a schematic cross-sectional view illustrating the package structure according to a fifth embodiment of the present invention;

FIG. 3B is a schematic cross-sectional view illustrating the package structure according to a sixth embodiment of the present invention;

FIG. 4A is a schematic cross-sectional view illustrating the package structure according to a seven embodiment of the present invention;

FIG. 4B is a schematic cross-sectional view illustrating the package structure according to an eight embodiment of the present invention;

FIG. 5 is a schematic perspective view illustrating a power assembly according to an embodiment of the present invention, wherein plural package structures are mounted on and connected to a printed circuit board to form the power assembly;

FIGS. 6A to 61 are schematic cross-sectional views illustrating a packaging process according to a first embodiment of the present invention; and

FIGS. 7A to 7K are schematic cross-sectional views illustrating a packaging process according to a second embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items. While the numerical ranges and parameters set forth for the broad scope of the present invention are approximations, the numerical value reported in the specific examples set forth as accurately as possible. However, any numerical values inherently contain certain errors necessarily the standard deviation found in the respective testing measurements caused. Also, as used herein, the term “about” generally means away from a given value or a range of 10%, 5%, 1% or 0.5%. Alternatively, the word “about” means within an acceptable standard error of ordinary skill in the art-recognized average. In addition to the operation/working examples, or unless otherwise specifically stated otherwise, in all cases, all of the numerical ranges, amounts, values and percentages, such as the number for the herein disclosed materials, time duration, temperature, operating conditions, the ratio of the amount, and the like, should be understood as the word “about” decorator. Accordingly, unless otherwise indicated, the numerical parameters of the present invention and scope of the appended patent proposed is to follow changes in the desired approximations. At least, the number of significant digits for each numerical parameter should at least be reported and explained by conventional rounding technique is applied. Herein, it can be expressed as a range between from one endpoint to the other or both endpoints. Unless otherwise specified, all ranges disclosed herein are inclusive.

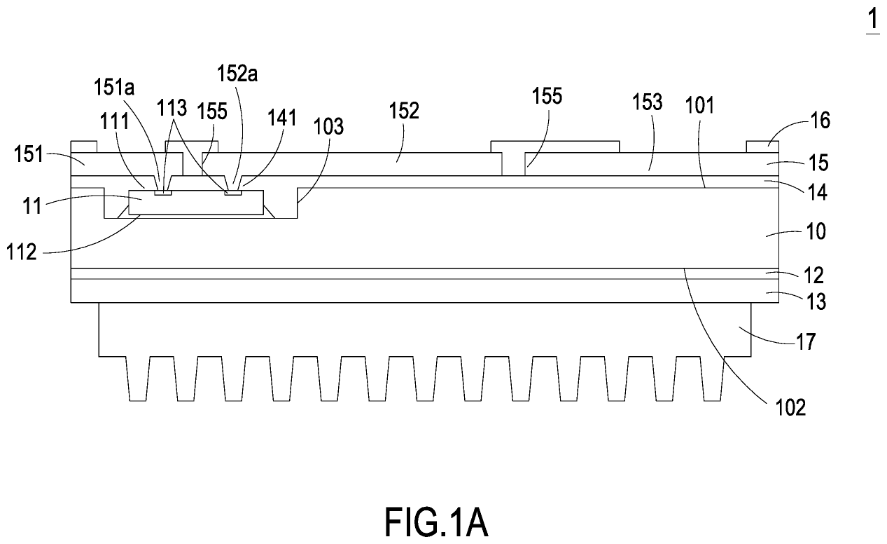

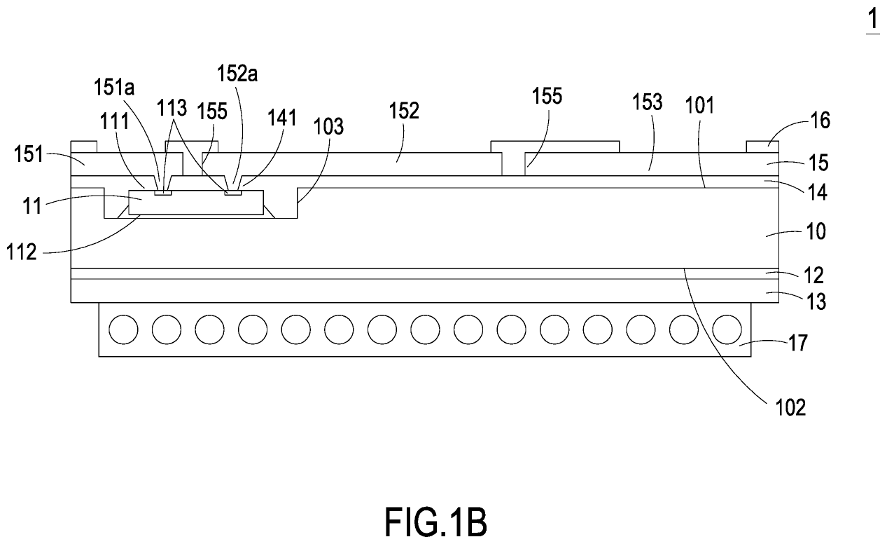

Please refer to FIG. 1A, which is a schematic cross-sectional view illustrating a package structure according to a first embodiment of the present invention. The package structure 1 includes a carrier 10, at least one electronic component 11, a first insulation layer 12, a heat spreading layer 13, a second insulation layer 14, a re-distribution layer 15, a passivation layer 16, and a heat dissipation device 17. The carrier 10 has a first surface 101, a second surface 102, and at least one first recess 103. The first surface 101 is opposite to the second surface 102. The first recess 103 is concavely formed on the first surface 101 of the carrier 10. In this embodiment, the carrier 10 includes a lead frame made of metallic material. Preferably but not exclusively, the lead frame is thick and made of copper. The electronic component 11 includes a first surface 111, a second surface 112, and a plurality of conducting terminals 113. The first surface 111 of the electronic component 11 is opposite to the second surface 112 of the electronic component 11. The conducting terminals 113 are formed on the first surface 111 of the electronic component 11. The electronic component 11 is disposed in the first recess 103 of the carrier 10. The first surface 111 of the electronic component 11 is exposed from the carrier 10 and coplanar with the first surface 101 of the carrier 10, and the second surface 112 of the electronic component 11 is attached to a bottom surface of the first recess 103 of the carrier 10. In this embodiment, the electronic component 11 includes an active component, such as a chip of a power semiconductor device. Preferably but not exclusively, the power semiconductor device includes a Si-based power semiconductor device, or a Wide Band Gap (WBG) power semiconductor device, such as Gallium Nitride (GaN) device or Silicon Carbide (SiC) device. Consequently, the package structure 1 with Wide Band Gap (WBG) power semiconductor device may achieve the purposes of high power and high frequency operation. It is noted that the active component is not limited to the above embodiment and may be varied according to the practical requirements. The number of the conducting terminals 113 of the electronic component 11 is determined according to the type and the configuration of the electronic component 11. In this embodiment, the number of the conducting terminals 113 are two, but not limited thereto. In one embodiment, the electronic component 11 includes a lateral power device.

The first insulation layer 12 is formed on the second surface 102 of the carrier 10. The first insulation layer 12 may be made of resin or any appropriate insulation material with high thermal conductivity.

The heat spreading layer 13 is formed on a surface of the first insulation layer 12. Namely, the first insulation layer 12 and the heat spreading layer 13 are disposed on the same side of the carrier 10. In this embodiment, the heat spreading layer 13 includes a re-distribution layer made of metallic material, for example but not limited to copper foil.

The second insulation layer 14 is formed on the first surface 101 of the carrier 10 and covers the at least one electronic component 11 disposed in the first recess 103. The second insulation layer 14 and the first insulation layer 12 are disposed on opposed sides of the carrier 10. The second insulation layer 14 has a plurality of via holes 141 corresponding in position to the conducting terminals 113 of the electronic component 11, respectively. The second insulation layer 14 may be made of resin or any appropriate insulation material with high thermal conductivity. Preferably but not exclusively, the first insulation layer 12 and the second insulation layer 14 may be made of same materials.

The re-distribution layer 15 is formed on a surface of the second insulation layer 14 and covers the second insulation layer 14. The re-distribution layer 15 includes a plurality of re-distribution blocks. In this embodiment, the re-distribution layer 15 includes for example a first re-distribution block 151, a second re-distribution block 152, and a third re-distribution block 153, which are separated with each other through plural grooves 155. The first re-distribution block 151 and the second re-distribution block 152 have first conductive vias 151a, 152a, respectively. The first conductive vias 151a, 152a are formed in the via holes 141 of the second insulation layer 14, respectively. The first re-distribution block 151 is connected with one conductive terminal 113 of the electronic component 11 through the first conductive via 151a. The second re-distribution block 151 is connected with the other conductive terminal 113 of the electronic component 11 through the first conductive via 152a. In this embodiment, the re-distribution layer 15 is made of metallic material, for example but not limited to copper.

The passivation layer 16 is formed on a surface of the re-distribution layer 15 and covers portion of the re-distribution layer 15. Portion of the passivation layer 16 is filled into the grooves 155 so that the first re-distribution block 151, the second re-distribution block 152, and the third re-distribution block 153 are separated with each other. In this embodiment, portion of the first re-distribution block 151, portion of the second re-distribution block 152, and portion of the third re-distribution block 153 are exposed from the passivation layer 16. Consequently, the first re-distribution block 151 and the second re-distribution block 152 are served as the contact pads to be electrically connected with corresponding contact elements of a printed circuit board (not shown). In this embodiment, the passivation layer 16 is made of a resin or any other appropriate insulation material with high thermal conductivity.

The heat dissipation device 17 is disposed on a surface of the heat spreading layer 13 for enhancing the heat dissipating efficiency of the package structure 1. The heat dissipation device 17 may include a passive heat dissipation device (see FIG. 1A) or an active heat dissipation device (see FIG. 1B). An example of the passive heat dissipation device includes but not limited to a heat sink made of metallic material or ceramic material. An example of the active heat dissipation device includes but not limited to a heat pipe or a liquid cooling device. In some embodiments, the heat dissipation device 17 may be fixed on the surface of the heat spreading layer 13 by a thermal interface material (not shown), for example a heat conduction glue.

As mentioned above, since the electronic component 11 is disposed in the first recess 103 of the carrier 10. In one embodiment, the carrier 10 may be a metallic lead frame, the heat spreading layer 13 is formed on the lead frame, and the heat dissipation device 17 is mounted on the heat spreading layer 13, so that the lead frame, the first insulation layer 12, the heat spreading layer 13, and the heat dissipation device 17 form a primary cooling channel for dissipating the heat from the electronic component 11 to the surroundings. In addition, the first re-distribution block 151 and the second re-distribution block 152 are connected with the electronic component 11 and exposed from the passivation layer 16 so that the re-distribution layer 15 forms a secondary cooling channel for dissipating the heat from the electronic components 11 to the surroundings. Moreover, a portion of the heat generated by the electronic component 11 also may be transferred to the surroundings through the lateral sides of the lead frame. Even if the electronic component 11 generates a great amount of heat during working, the heat generated by the electronic component 11 may be rapidly transferred to the surroundings of the package structure 1. Consequently, the heat dissipating efficiency is enhanced. In addition, no wire bonding and no direct bonded copper substrate are employed in the package structure 1 of the embodiment, so that the overall thickness of the package structure 1 may be reduced, and the cost is reduced.

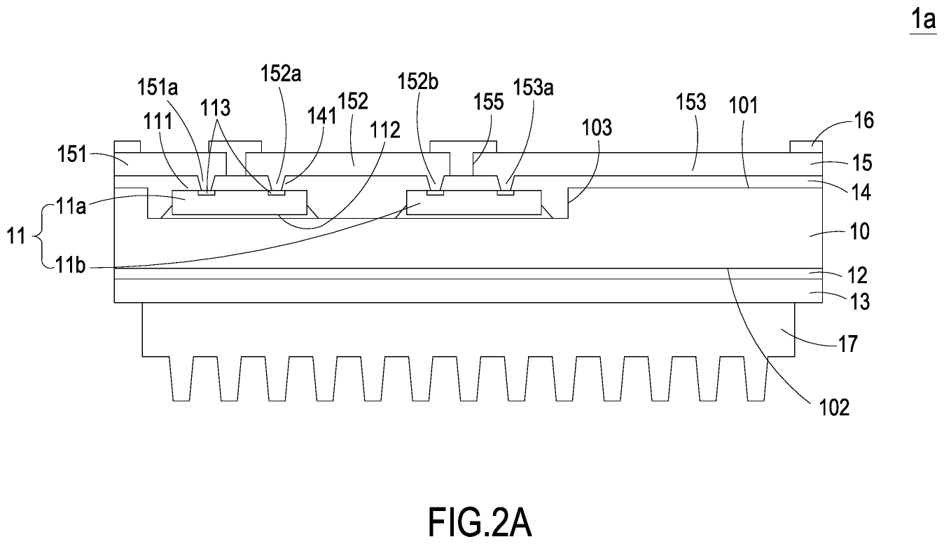

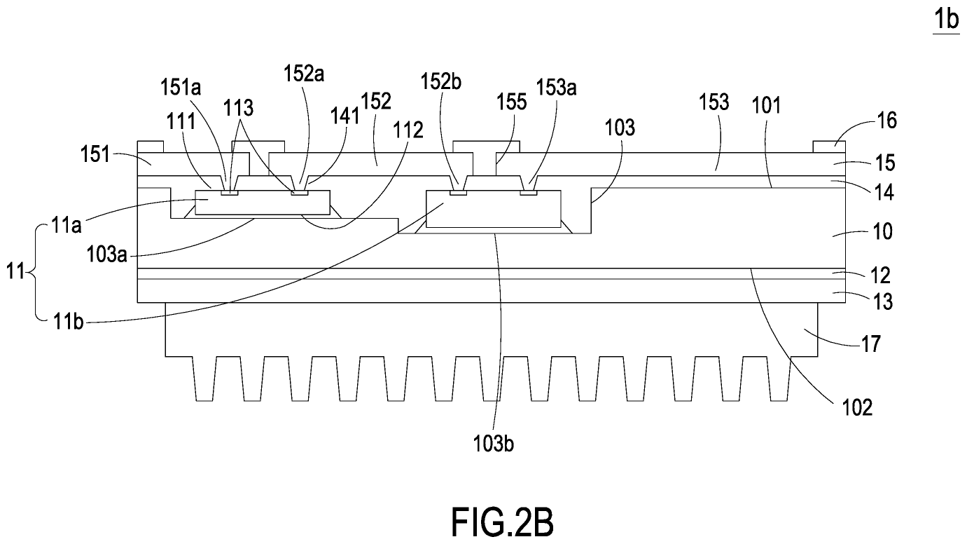

Please refer to FIG. 2A, which is a schematic cross-sectional view illustrating a package structure according to a third embodiment of the present invention. In this embodiment, the component parts and elements similar to those of FIG. 1A are designated by identical numeral references, and are not redundantly described herein. In this embodiment, the package structure 1a includes a plurality of electronic component 11, for example a first electronic component 11a and a second electronic component 11b. The first electronic component 11a and the second electronic component 11b have same thicknesses. The first electronic component 11a and the second electronic component 11b are disposed in the first recess 103 of the carrier 10 and spaced apart with each other. The first surfaces 111 of the first electronic component 11a and the second electronic component 11b are exposed from the carrier 10 and coplanar with the first surface 101 of the carrier 10. Consequently, the electronic components 11 may be embedded in the package structure 1a to achieve slim and compact purposes. In addition, the first re-distribution block 151 has a first conductive via 151a connected with one conductive terminal 113 of the first electronic component 11a. The second re-distribution block 152 has a first conductive via 152a connected with the other conductive terminal 113 of the first electronic component 11a and a second conductive via 152b connected with one conductive terminal 113 of the second electronic component 11b. The third re-distribution block 153 has a first conductive via 153a connected with the other conductive terminal 113 of the second electronic component 11b. The first re-distribution block 151, the second re-distribution block 152, and the third re-distribution block 153 are severed as contact pads for electrically connected to corresponding contact elements of a printed circuit board (not shown).

Please refer to FIG. 2B, which is a schematic cross-sectional view illustrating a package structure according to a fourth embodiment of the present invention. In this embodiment, the component parts and elements similar to that of FIG. 2A are designated by identical numeral references, and are not redundantly described herein. In comparing with the package structure 1a, the package structure 1b includes a plurality of electronic components 11 with different thicknesses. In this embodiment, the first electronic component 11a and the second electronic component 11b have different thicknesses. The thickness of the second electronic component 11b is greater than that of the first electronic component 11a. The bottom surface of the first recess 103 has a stepped structure including a first plane 103a and a second plane 103b. The distance from the first surface 101 to the first plane 103a is shorter than the distance from the first surface 101 to the second plane 103b. The first electronic component 11a is disposed on the first plane 103a, and the second electronic component 11b is disposed on the second plane 103b. The first surfaces 111 of the first electronic component 11a and the second electronic component 11b are exposed from the carrier 10 and coplanar with the first surface 101 of the carrier 10. Consequently, the electronic components 11 with different thicknesses may be embedded in the package structure 1b to achieve slim and compact purposes.

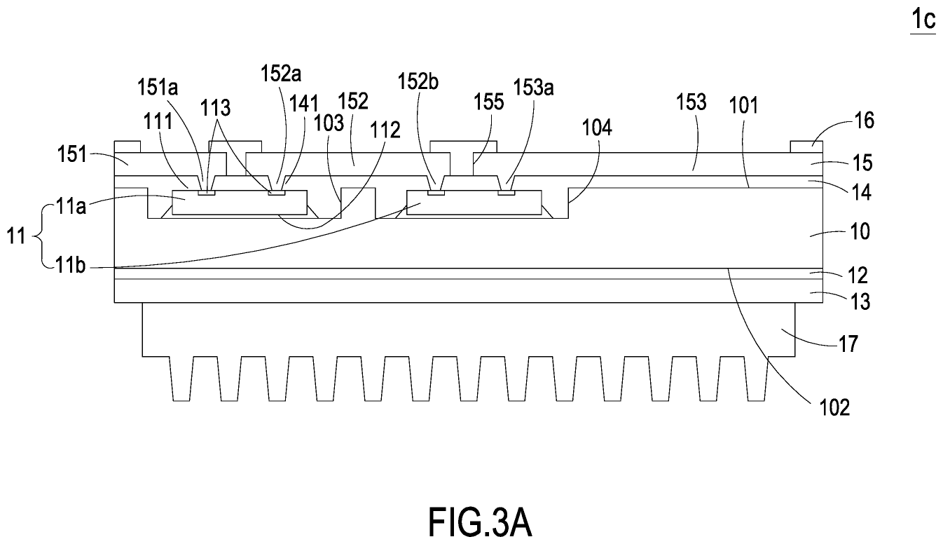

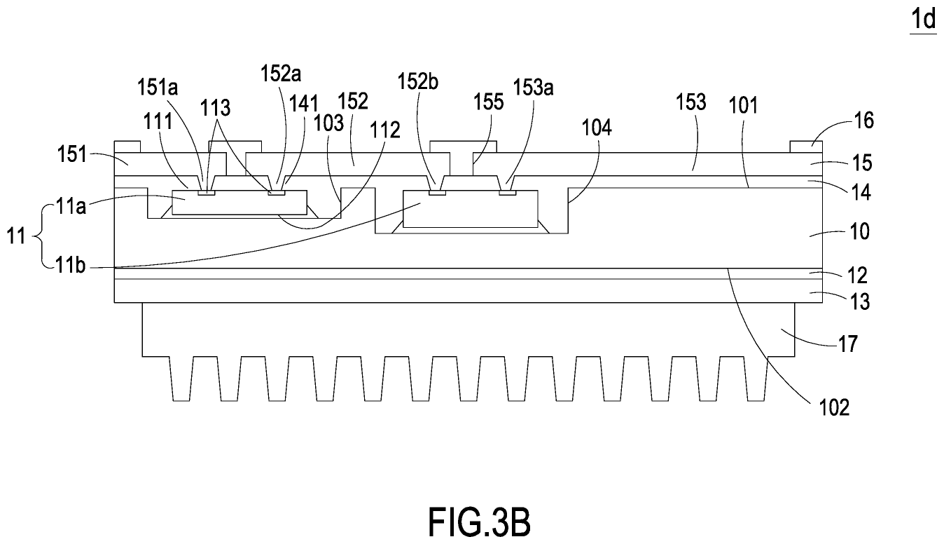

Please refer to FIG. 3A, which is a schematic cross-sectional view illustrating a package structure according to a fifth embodiment of the present invention. In this embodiment, the component parts and elements similar to that of FIG. 2A are designated by identical numeral references, and are not redundantly described herein. In comparing with the package structure 1a, the package structure 1c includes a first recess 103 and a second recess 104 separated with each other. In this embodiment, the first electronic component 11a and the second electronic component 11b have same thicknesses. The first electronic component 11a is disposed in the first recess 103, and the second electronic component 11b is disposed in the second recess 104. The first surfaces 111 of the first electronic component 11a and the second electronic component 11b are exposed from the carrier 10 and coplanar with the first surface 101 of the carrier 10. Consequently, the electronic components 11 may be embedded in the package structure 1c to achieve slim and compact purposes.

Please refer to FIG. 3B, which is a schematic cross-sectional view illustrating a package structure according to a sixth embodiment of the present invention. In this embodiment, the component parts and elements similar to that of FIG. 3A are designated by identical numeral references, and are not redundantly described herein. In comparing with the package structure 1c, the package structure 1d includes a plurality of electronic components 11 with different thicknesses. In this embodiment, the first electronic component 11a and the second electronic component 11b have different thicknesses, and the first recess 103 and the second recess 104 have different depths. The thickness of the second electronic component 11b is greater than that of the first electronic component 11a. The depth of the second recess 104 is greater than that of the first recess 103. The first electronic component 11a is disposed in the first recess 103, and the second electronic component 11b is disposed in the second recess 104. The first surfaces 111 of the first electronic component 11a and the second electronic component 11b are exposed from the carrier 10 and coplanar with the first surface 101 of the carrier 10. Consequently, the electronic components 11 with different thicknesses may be embedded in the package structure 1d to achieve slim and compact purposes.

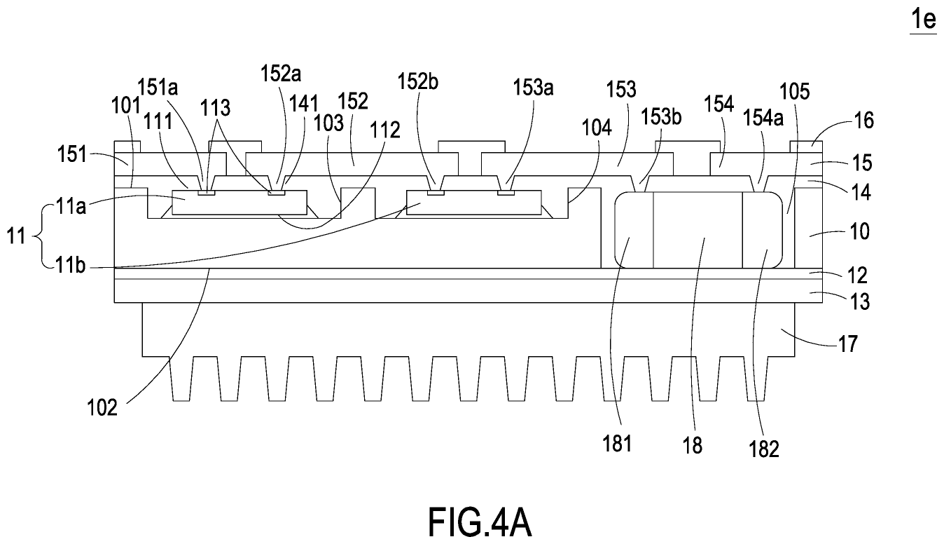

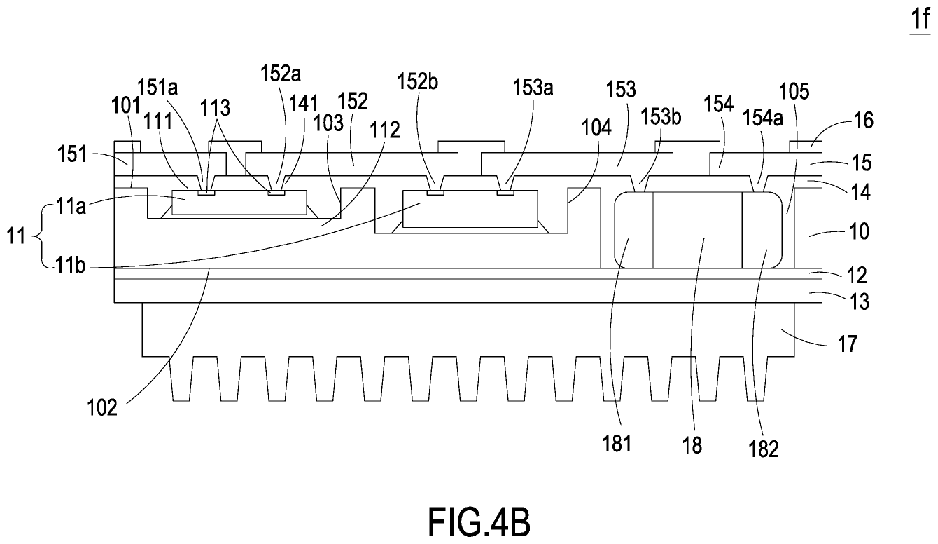

Please refer to FIG. 4A, which is a schematic cross-sectional view illustrating a package structure according to a seventh embodiment of the present invention. In this embodiment, the component parts and elements similar to that of FIG. 3A are designated by identical numeral references, and are not redundantly described herein. In comparing with the package structure 1c, the package structure 1e further includes at least one passive component 18. The passive component 18 includes a first conductive terminal 181 and a second conductive terminal 182. In this embodiment, the passive component 18 may be for example but not limited to a diode, an inductor, a transformer or a chock. The carrier 10 further has a through hole 105. The passive component 18 is disposed in the through hole 105 of the carrier 10. The first surfaces 111 of the first electronic component 11a and the second component 11b and one surface of the passive component 18 are exposed from the carrier 10 and coplanar with the first surface 101 of the carrier 10. The other surface of the passive component 18 is coplanar with the second surface 102 of the carrier 10. Consequently, the electronic components 11 and the passive component 18 may be embedded in the package structure 1e to achieve slim and compact purposes. In addition, the re-distribution layer 15 includes a first re-distribution block 151, a second re-distribution block 152, a third re-distribution block 153, and a fourth re-distribution block 154. The first re-distribution block 151 has a first conductive via 151a connected with one conductive terminal 113 of the first electronic component 11a. The second re-distribution block 152 has a first conductive via 152a connected with the other conductive terminal 113 of the first electronic component 11a and a second conductive via 152b connected with one conductive terminal 113 of the second electronic component 11b. The third re-distribution block 153 has a first conductive via 153a connected with the other conductive terminal 113 of the second electronic component 11b and a second conductive via 153b connected with the first conductive terminal 181 of the passive component 18. The fourth re-distribution block 154 has a first conductive via 154a connected with the second conductive terminal 182 of the passive component 18. The first re-distribution block 151, the second re-distribution block 152, the third re-distribution block 153, and the fourth re-distribution 154 are severed as contact pads for electrically connected to corresponding contact elements of a printed circuit board (not shown).

Please refer to FIG. 4B, which is a schematic cross-sectional view illustrating a package structure according to an eight embodiment of the present invention. In this embodiment, the component parts and elements similar to those of FIG. 4A are designated by identical numeral references, and are not redundantly described herein. In comparing with the package structure 1e, the package structure 1f includes a plurality of electronic components 11 with different thicknesses. In this embodiment, the first electronic component 11a and the second electronic component 11b have different thicknesses, and the first recess 103 and the second recess 104 have different depths. The thickness of the second electronic component 11b is greater than that of the first electronic component 11a. The depth of the second recess 104 is greater than that of the first recess 103. The first electronic component 11a is disposed in the first recess 103, the second electronic component 11b is disposed in the second recess 104, and the passive component 18 is disposed in the through hole 105 of the carrier 10. The first surfaces 111 of the first electronic component 11a and the second component 11b and one surface of the passive component 18 are exposed from the carrier 10 and coplanar with the first surface 101 of the carrier 10. The other surface of the passive component 18 is coplanar with the second surface 102 of the carrier 10. Consequently, the electronic components 11 with different thicknesses and the passive component 18 may be embedded in the package structure 1f to achieve slim and compact purposes.

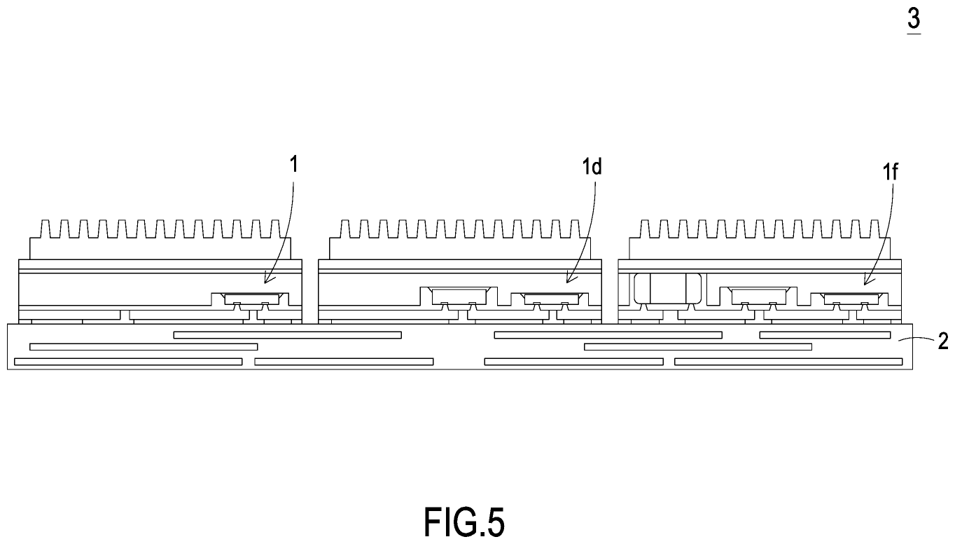

Please refer to FIG. 5, which is a schematic perspective view illustrating a power assembly according to an embodiment of the present invention, wherein plural package structures are mounted on and connected to a printed circuit board to form the power assembly. In this embodiment, plural package structures including for example a package structure 1, a package structure 1d, and a package structure 1f are mounted on the printed circuit board 2 through surface mount technology. Consequently, the package structures 1, 1d, 1f are electrically connected to the printed circuit board 2 and form a power assembly 3. It is noted that numbers and structures of the plural package structures employed in the power assembly 3 are not limited to the above embodiments and may be varied according to the practical requirements. In this embodiment, the primary cooling channels of the plural package structures 1, 1d, 1f are arranged on the same side of the printed circuit board 3. Consequently, the heat dissipating efficiency is enhanced.

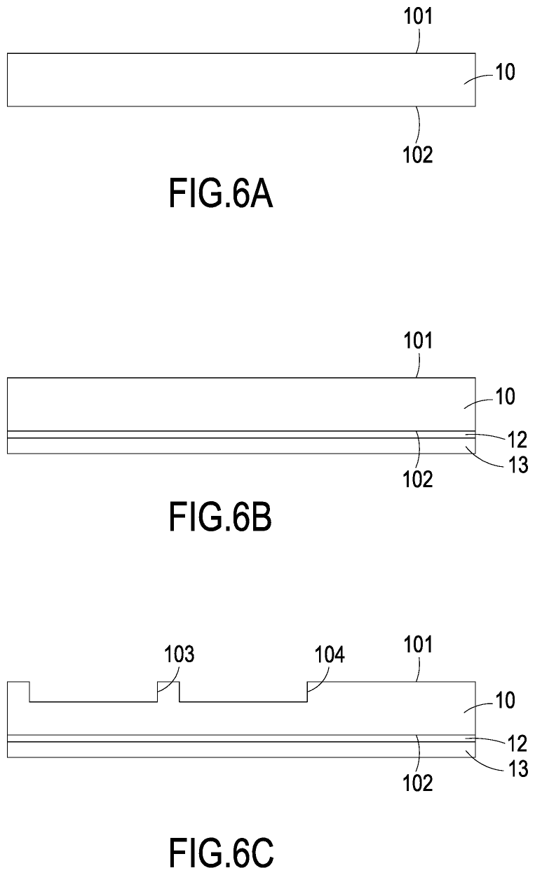

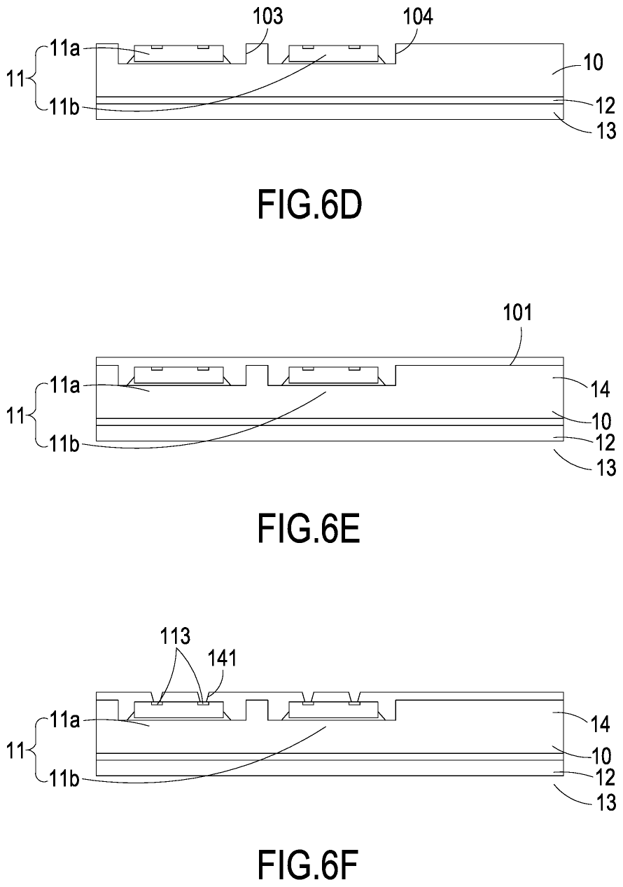

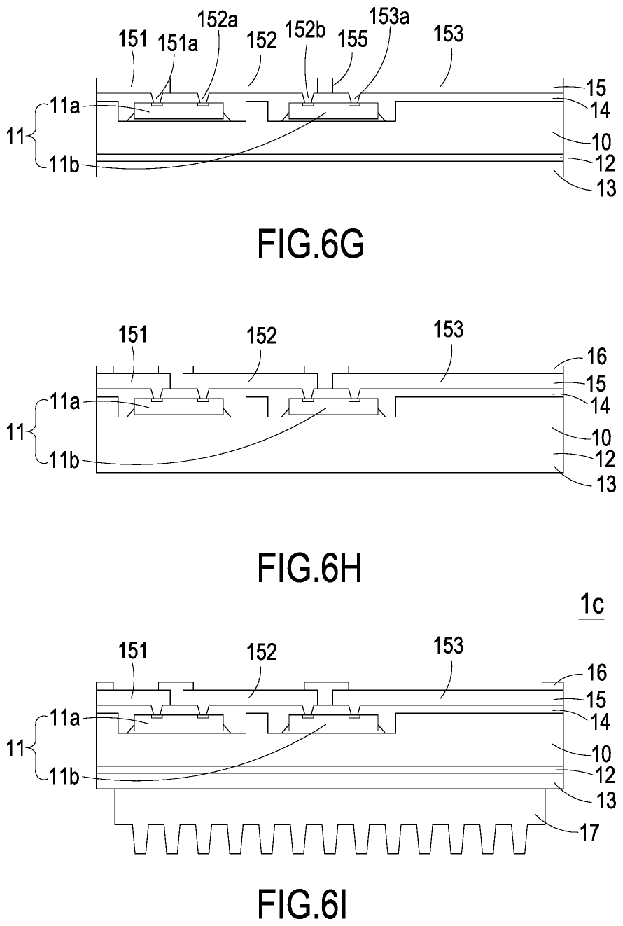

FIGS. 6A to 61 are schematic cross-sectional views illustrating a packaging process according to a first embodiment of the present invention. Firstly, as shown in FIG. 6A, a carrier 10 is provided. In this embodiment, the carrier 10 includes a lead frame made of metallic material. Preferably but not exclusively, the lead frame is thick and made of copper. Then, as shown in FIG. 6B, a first insulation layer 12 is formed on the surface 102 of the carrier 10, and a heat spreading layer 13 is formed on a surface of the first insulation layer 12. Then, as shown in FIG. 6C, at least one recess is formed on the first surface 101 of the carrier 10. In this embodiment, a first recess 103 and a second recess 104 are formed on the first surface 101 of the carrier 10. The first recess 103 and the second recess 104 are formed on the carrier 10 by an etching process.

Then, as shown in FIG. 6D, at least one electronic component 11 is provided. The at least one electronic component 11 is disposed in the recess and attached to the bottom surface of the recess. In this embodiment, a first electronic component 11a is disposed in the first recess 103, and a second electronic component 11b is disposed in the second recess 104. Then, as shown in FIG. 6E, a second insulation layer 14 is formed on the first surface 101 of the carrier 10 and covers the at least one electronic component 11 in the recess. Preferably but not exclusively, the second insulation layer 14 is formed by performing a lamination and curing process. After the step as shown in FIG. 6E, a semi-package structure 4 is formed. Then, as shown in FIG. 6F, a plurality of via holes 141 are formed in the second insulation layer 14. The plurality via holes 141 are corresponding in position to the conductive terminals 113 of the electronic component 11, respectively. In this embodiment, the plurality of via holes 141 are formed in the second insulation layer 14 by a laser drilling process.

Then, as shown in FIG. 6G, a re-distribution layer 15 is formed on the second insulation layer 14 and a plurality of grooves 155 are formed in the re-distribution layer 15 to form a plurality of re-distribution blocks separated with each other. In this embodiment, the plurality of re-distribution blocks includes a first re-distribution block 151, a second re-distribution block 152, and a third re-distribution block 153 separated with each other. The first re-distribution block 151 has a first conductive via 151a disposed in the second insulation layer 14 and in contact with one conductive terminal 113 of the first electronic component 11a. The second re-distribution block 152 has a first conductive via 152a disposed in the second insulation layer 14 and in contact with the other conductive terminal 113 of the first electronic component 11a and a second conductive via 152b disposed in the second insulation layer 14 and in contact with one conductive terminal 113 of the second electronic component 11b. The third re-distribution block 153 has a first conductive via 153a disposed in the second insulation layer 14 and in contact with the other conductive terminal 113 of the second electronic component 11b. In this embodiment, the re-distribution layer 15 is made of copper. Then, as shown in FIG. 6H, a passivation layer 16 is formed on the re-distribution layer 15 to cover portions of the re-distribution blocks 151, 152, 153 and disposed in the grooves 155. In this embodiment, portion of the first re-distribution block 151, portion of the second re-distribution block 152, and portion of the third re-distribution block 153 are exposed from the passivation layer 16. The first re-distribution block 151, the second re-distribution block 152, and the third re-distribution block 153 are severed as contact pads. Finally, as shown in FIG. 6I, a heat dissipation device 17 is provided and disposed on a surface of the heat spreading layer 13. Consequently, the package structure 1c is fabricated. It is noted that the packaging processes for fabricating the above package structures 1, 1a, 1b, 1d are similar with that of this embodiment, and are not redundantly described herein.

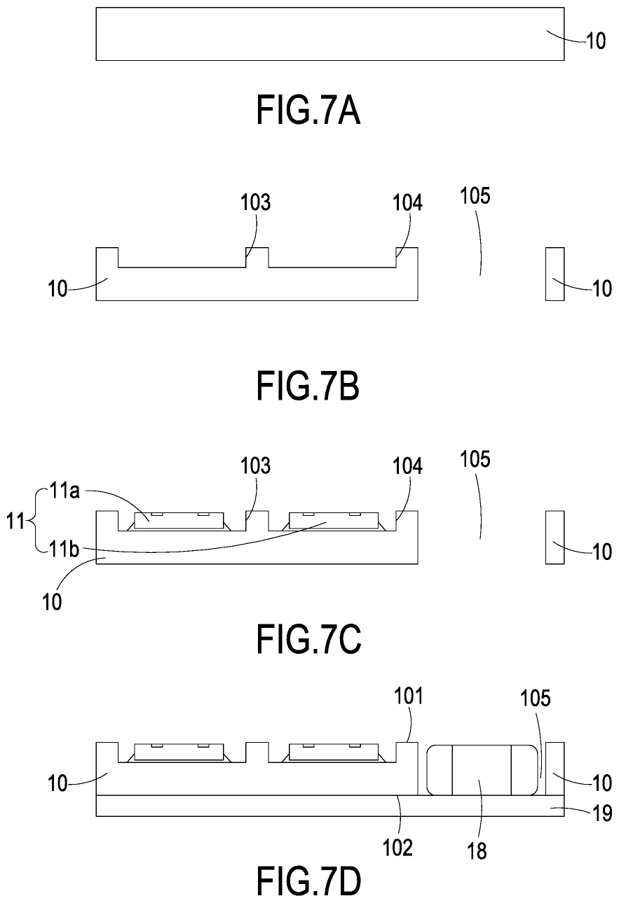

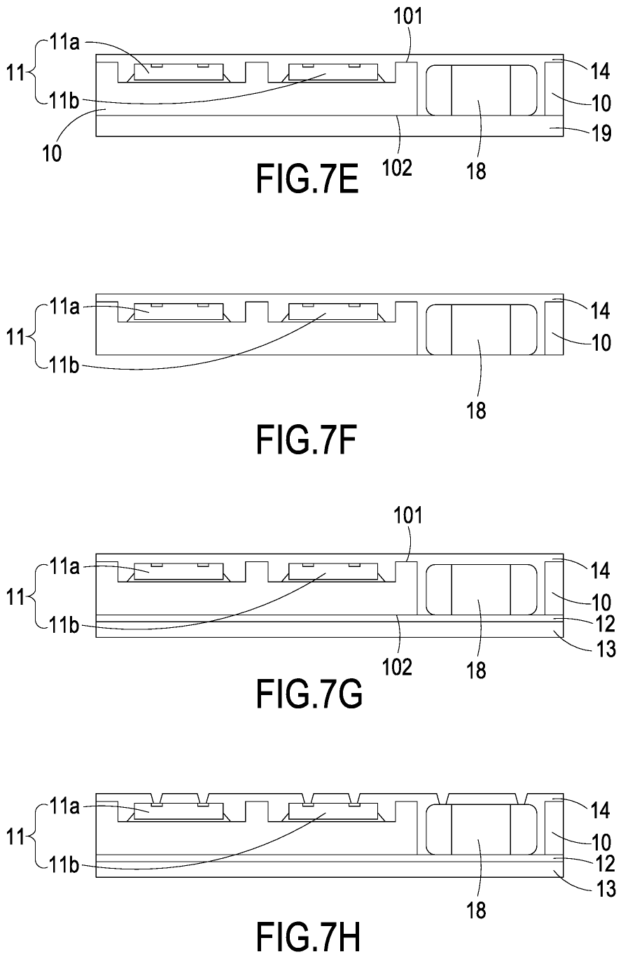

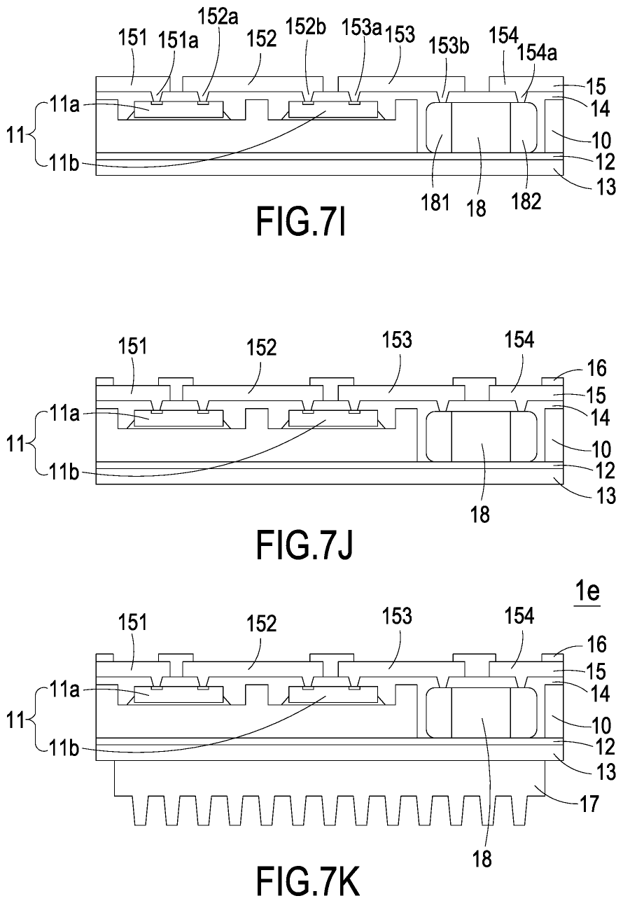

FIGS. 7A to 7K are schematic cross-sectional views illustrating a packaging process according to a second embodiment of the present invention. Firstly, as shown in FIG. 7A, a carrier 10 is provided. In this embodiment, the carrier 10 includes a lead frame made of metallic material. Preferably but not exclusively, the lead frame is thick and made of copper. Then, as shown in FIG. 7B, at least one recess is formed on the first surface 101 of the carrier 10 and at least one through hole 105 is formed in the carrier 10. In this embodiment, a first recess 103 and a second recess 104 are formed on the first surface 101 of the carrier 10, and a through hole 105 is formed in the carrier 10. The first recess 103 and the second recess 104 are formed on the carrier 10 by an etching process, and the through hole 105 is formed in the carrier 10 by the etching process. Then, as shown in FIG. 7C, at least one electronic component 11 is disposed in the recess and attached to the bottom surface of the recess. In this embodiment, a first electronic component 11a is disposed in the first recess 103, and a second electronic component 11b is disposed in the second recess 104. The first electronic component 11a and the second electronic component 11b are attached to the bottom surfaces of the first recess 103 and the second recess 104 by a solder material respectively, and then a reflow process is performed. Consequently, the first electronic component 11a and the second electronic component 11b are fixed on the bottom surfaces of the first recess 103 and the second recess 104, respectively.

Then, as shown in FIG. 7D, a thermal release layer 19 is provided and attached on the second surface 102 of the carrier 10. Then, at least one passive component 18 is disposed in the through hole 105 and attached to the thermal release layer 19. Since the at least one passive component 18 is adhered on the thermal release layer 19, the at least one passive component 18 is temporarily fixed on the thermal release layer 19. In this embodiment, the thermal release layer 19 is a thermal release tape. Then, as shown in FIG. 7E, a second insulation layer 14 is formed on the first surface 101 of the carrier 10 and covers the at least one electronic component 11 and the at least one passive component 18. In this embodiment, the second insulation layer 14 covers the first electronic component 11a, the second electronic component 11b, and the passive component 18. Preferably but not exclusively, the second insulation layer 14 is formed by performing a lamination and curing process. Thereafter, as shown in FIG. 7F, the thermal release layer 19 is removed.

Then, as shown in FIG. 7G, a first insulation layer 12 is formed on the surface 102 of the carrier 10, and a heat spreading layer 13 is formed on a surface of the first insulation layer 12. After the step as shown in FIG. 7G, a semi-package structure 4 is formed. Then, as shown in FIG. 7H, a plurality of via holes 141 are formed in the second insulation layer 14. In this embodiment, the plurality of via holes 141 are formed in the second insulation layer 14 by a laser drilling process.

Then, as shown in FIG. 7I, a re-distribution layer 15 is formed on the second insulation layer 14 and a plurality of grooves 155 are formed in the re-distribution layer 15 to form a plurality of re-distribution blocks separated with each other. In this embodiment, the plurality of re-distribution blocks includes a first re-distribution block 151, a second re-distribution block 152, a third re-distribution block 153, and a fourth re-distribution block 154 separated with each other. The first re-distribution block 151 has a first conductive via 151a disposed in the second insulation layer 14 and in contact with one conductive terminal 113 of the first electronic component 11a. The second re-distribution block 152 has a first conductive via 152a disposed in the second insulation layer 14 and in contact with the other conductive terminal 113 of the first electronic component 11a and a second conductive via 152b disposed in the second insulation layer 14 and in contact with one conductive terminal 113 of the second electronic component 11b. The third re-distribution block 153 has a first conductive via 153a disposed in the second insulation layer 14 and in contact with the other conductive terminal 113 of the second electronic component 11b and a second conductive via 153b disposed in the second insulation layer 14 and in contact with the first conductive terminal 181 of the passive component 18. The fourth re-distribution block 154 has a first conductive via 154a disposed in the second insulation layer 14 and in contact with the second conductive terminal 182 of the passive component 18. In this embodiment, the re-distribution layer 15 is made of copper.

Then, as shown in FIG. 7J, a passivation layer 16 is formed on the re-distribution layer 15 to cover portions of the re-distribution blocks 151, 152,153,154 and disposed in the grooves 155. In this embodiment, portion of the first re-distribution block 151, portion of the second re-distribution block 152, portion of the third re-distribution block 153, and portion of the fourth re-distribution block 154 are exposed from the passivation layer 16. The first re-distribution block 151, the second re-distribution block 152, the third re-distribution block 153, and the fourth re-distribution block 154 are severed as contact pads. Finally, as shown in FIG. 7K, a heat dissipation device 17 is provided and disposed on a surface of the heat spreading layer 13. Consequently, the packaged structure 1e is fabricated. It is noted that the packaging processes for fabricating the above package structure 1f is similar with that of this embodiment, and are not redundantly described herein.

From the above descriptions, the embodiments of the present invention provides some package structures and packaging processes. One or more electronic components are disposed in at least one recess of a thick carrier and a multiple sides cooling mechanism is employed to dissipate the heat to the surroundings. In some embodiments, the thick carrier includes a thick lead frame. Consequently, the overall thickness of the package structure is reduced, and the heat dissipating efficiency is enhanced. In addition, at least one electronic component and at least one passive component are separately and horizontally disposed in a carrier, covered by insulation layers and electrically connected via a plurality of re-distribution blocks. Consequently, the overall thickness of the package structure is reduced, and the high power density and compact purpose are achieved. Furthermore, the packaging process for a slim and easily fabricated package structure is simplified and cost-efficient.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A package structure, comprising:
a carrier having a first surface, a second surface, and at least one recess, wherein the first surface is opposite to the second surface, and the at least one recess is concavely formed on the first surface of the carrier;
at least one electronic component disposed in the at least one recess, wherein each of the at least one electronic component has a first surface, a second surface, and a plurality of conducting terminals, the first surface is opposite to the second surface, the plurality of conducting terminals are formed on the first surface of the electronic component, and the first surface of the electronic component is coplanar with the first surface of the carrier;
a first insulation layer formed on the second surface of the carrier;
a heat spreading layer formed on the first insulation layer;
a second insulation layer formed on the first surface of the carrier and covering the at least one electronic component disposed in the at least one recess;
a plurality of re-distribution blocks formed on the second insulation layer and separated with each other, wherein each of the plurality of re-distribution blocks comprises at least one conductive via disposed in the second insulation layer and in contact with corresponding one of the plurality of conductive terminals;
a passivation layer formed on the plurality of the re-distribution blocks and covering portions of the plurality of the re-distribution blocks; and
a heat dissipation device disposed on the heat spreading layer.

2. The package structure according to claim 1, wherein the carrier comprises a lead frame made of a metallic material.

3. The package structure according to claim 1, wherein the electronic component comprises an active component.

4. The package structure according to claim 3, wherein the active component comprises a Si-based power semiconductor device or a Wide Band Gap power semiconductor device.

5. The package structure according to claim 1, wherein the heat spreading layer comprises a re-distribution layer made of a metallic material.

6. The package structure according to claim 1, wherein the heat dissipation device comprises a passive heat dissipation device or an active heat dissipation device.

7. The package structure according to claim 1, wherein the plurality of re-distribution blocks comprises a first re-distribution block and a second re-distribution block, each of the first re-distribution block and the second re-distribution block comprises a first conductive via, the first conductive via of the first re-distribution block is in contact with one conductive terminal of the electronic component, and the first conductive via of the second re-distribution block is in contact with the other conductive terminal of the electronic component.

8. The package structure according to claim 1, wherein the at least one electronic component comprises a first electronic component and a second electronic component disposed in the recess, and the first surfaces of the first electronic component and the second component are coplanar with the first surface of the carrier.

9. The package structure according to claim 8, wherein the plurality of re-distribution blocks comprises a first re-distribution block, a second re-distribution block, and a third re-distribution block, the first re-distribution block comprises a first conductive via, the second re-distribution block comprises a first conductive via and a second conductive via, and the third re-distribution block comprises a first conductive via, wherein the first conductive via of the first re-distribution block is in contact with one conductive terminal of the first electronic component, the first conductive via of the second re-distribution block is in contact with the other conductive terminal of the first electronic component, the second conductive via of the second re-distribution block is in contact with one conductive terminal of the second electronic component, and the first conductive via of the third re-distribution block is in contact with the other conductive terminal of the second electronic component.

10. The package structure according to claim 8, wherein the first electronic component and the second electronic component have different thickness.

11. The package structure according to claim 1, wherein the at least one electronic component comprises a first electronic component and a second electronic component, the at least one recess comprises a first recess and a second recess separated with each other, the first electronic component is disposed in the first recess, the second electronic component is disposed in the second recess, and the first surfaces of the first electronic component and the second component are coplanar with the first surface of the carrier.

12. The package structure according to claim 11, wherein the plurality of re-distribution blocks comprises a first re-distribution block, a second re-distribution block, and a third re-distribution block, the first re-distribution block comprises a first conductive via, the second re-distribution block comprises a first conductive via and a second conductive via, and the third re-distribution block comprises a first conductive via, wherein the first conductive via of the first re-distribution block is in contact with one conductive terminal of the first electronic component, the first conductive via of the second re-distribution block is in contact with the other conductive terminal of the first electronic component, the second conductive via of the second re-distribution block is in contact with one conductive terminal of the second electronic component, and the first conductive via of the third re-distribution block is in contact with the other conductive terminal of the second electronic component.

13. The package structure according to claim 11, wherein the first electronic component and the second electronic component have different thickness.

14. The package structure according to claim 1, further comprising at least one passive component, wherein the carrier further comprises a through hole, the at least one passive component is disposed in the at least one through hole, wherein the passive component includes a first conductive terminal and a second conductive terminal, the first surface of the carrier is coplanar with one surface of the passive component, and the second surface of the carrier is coplanar with the other surface of the passive component.

15. The package structure according to claim 14, wherein the at least one electronic component comprises a first electronic component and a second electronic component disposed in the recess, and the first surfaces of the first electronic component and the second component are coplanar with the first surface of the carrier.

16. The package structure according to claim 15, wherein the plurality of re-distribution blocks comprises a first re-distribution block, a second re-distribution block, a third re-distribution block and a fourth re-distribution block, the first re-distribution block comprises a first conductive via, the second re-distribution block comprises a first conductive via and a second conductive via, the third re-distribution block comprises a first conductive via and a second conductive via, and the fourth re-distribution block comprises a first conductive via, wherein the first conductive via of the first re-distribution block is in contact with one conductive terminal of the first electronic component, the first conductive via of the second re-distribution block is in contact with the other conductive terminal of the first electronic component, the second conductive via of the second re-distribution block is in contact with one conductive terminal of the second electronic component, the first conductive via of the third re-distribution block is in contact with the other conductive terminal of the second electronic component, the second conductive via of the third re-distribution block is in contact with the first conductive terminal of the passive component, and the first conductive via of the fourth re-distribution block is in contact with the second conductive terminal of the passive component.

17. The package structure according to claim 14, wherein the at least one electronic component comprises a first electronic component and a second electronic component, the at least one recess comprises a first recess and a second recess separated with each other, the first electronic component is disposed in the first recess, the second electronic component is disposed in the second recess, and the first surfaces of the first electronic component and the second component are coplanar with the first surface of the carrier.

18. The package structure according to claim 17, wherein the plurality of re-distribution blocks comprises a first re-distribution block, a second re-distribution block, a third re-distribution block, and a fourth re-distribution block, the first re-distribution block comprises a first conductive via, the second re-distribution block comprises a first conductive via and a second conductive via, the third re-distribution block comprises a first conductive via and a second conductive via, and the fourth re-distribution block comprises a first conductive via, wherein the first conductive via of the first re-distribution block is in contact with one conductive terminal of the first electronic component, the first conductive via of the second re-distribution block is in contact with the other conductive terminal of the first electronic component, the second conductive via of the second re-distribution block is in contact with one conductive terminal of the second electronic component, the first conductive via of the third re-distribution block is in contact with the other conductive terminal of the second electronic component, the second conductive via of the third re-distribution block is in contact with the first conductive terminal of the passive component, and the first conductive via of the fourth re-distribution block is in contact with the second conductive terminal of the passive component.

19. The package structure according to claim 14, further comprising a printed circuit board, wherein the plurality of re-distribution blocks are served as contact pads and connected to the printed circuit board.

20. A packaging process, comprising:
providing a semi-package structure, wherein the semi-package structure comprises a carrier, at least one electronic component, a first insulation layer, a heat spreading layer, and a second insulation layer, wherein the carrier has a first surface, a second surface, and at least one recess, and the at least one recess is concavely formed on the first surface of the carrier, wherein the at least one electronic component is disposed in the at least one recess, each of the at least one electronic component has a first surface, a second surface, and a plurality of conducting terminals, the plurality of conducting terminals are formed on the first surface of the electronic component, and the first surface of the electronic component is coplanar with the first surface of the carrier, wherein the first insulation layer is formed on the second surface of the carrier, the heat spreading layer is formed on the first insulation layer, and the second insulation layer is formed on the first surface of the carrier and covers the at least one electronic component;
removing portion of the second insulation layer to form a plurality of via holes corresponding in position with the plurality of conductive terminals of the electronic component;
forming a plurality of re-distribution blocks on the second insulation layer, wherein the plurality of re-distribution blocks are separated with each other, and each of the plurality of the re-distribution blocks comprises at least one conductive via disposed in corresponding one of the plurality of via holes of the second insulation layer and in contact with corresponding one of the plurality of conductive terminals;
forming a passivation layer on the plurality of re-distribution blocks and covering portions of the plurality of re-distribution blocks; and
disposing a heat dissipation device on the heat spreading layer.

21. The packaging process according to claim 20, wherein the step of providing the semi-package structure comprises steps of:
providing the carrier having the first surface and the second surface;
forming the first insulation layer on the second surface of the carrier;
forming the heat spreading layer on the first insulation layer;
forming the at least one recess on the first surface of the carrier;
disposing the at least one electronic component in the at least one recess; and
forming the second insulation layer on the first surface of the carrier and covering the at least one electronic component.

22. The packaging process according to claim 20, wherein the step of providing the semi-package structure comprises steps of:
providing the carrier having the first surface and the second surface;
forming the at least one recess on the first surface of the carrier, and forming at least one through hole in the carrier;
disposing the at least one electronic component in the at least one recess;
attaching a thermal release layer on the second surface of the carrier;
disposing at least one passive component in the at least one through hole, wherein one surface of the passive component is coplanar with the first surface of the carrier, and the other surface of the passive component is coplanar with the second surface of the carrier;
forming the second insulation layer on the first surface of the carrier and covering the at least one electronic component and the at least one passive component;
removing the thermal release layer;
forming the first insulation layer on the second surface of the carrier; and
forming the heat spreading layer on the first insulation layer.

23. The packaging process according to claim 20, wherein the plurality of via holes of the second insulation layer are formed by a laser drilling process.

24. The packaging process according to claim 20, wherein the at least one recess is formed by an etching process.
